(19) United States
(12) Patent Application Publication
(10) Pub. No.: US 2026/0247932 A1
(43) Pub. Date: Aug. 20, 2026

(54) MONOCRYSTALLINE SILICON WAFER AND FORMING METHOD THEREFOR

(71) Applicants: ZING SEMICONDUCTOR CORPORATION, Shanghai (CN); SHANGHAI INSTITUTE OF MICROSYSTEM AND INFO. TECH., CHINESE ACADEMY OF SCIENCES, Shanghai (CN)

(72) Inventors: Yun LIU, Shanghai (CN); Huan TUO, Shanghai (CN); Xing WEI, Shanghai (CN); Zhongying XUE, Shanghai (CN)

(21) Appl. No.: 19/645,867

(22) Filed: Apr. 13, 2026

Related U.S. Application Data
(63) Continuation of application No. PCT/CN2024/122783, filed on Sep. 30, 2024.

(30) Foreign Application Priority Data
Oct. 12, 2023 (CN) 202311324353.2

(51) Int. Cl. H10P 90/00; H10D 62/10; H10D 62/83; H10P 70/00

(52) U.S. Cl. CPC H10P 90/14; H10D 62/102; H10D 62/83; H10P 70/10; H10P 90/123; H10P 90/128

(57) ABSTRACT

The present invention provides a monocrystalline silicon wafer and method of forming the wafer. The monocrystalline silicon wafer includes an upper surface and a first region located within a predefined distance from the upper surface, and the first region is free of self-interstitial defects. Semiconductor devices fabricated from such a monocrystalline silicon wafer free of self-interstitial defects will exhibit improved performance because of less leakage and a higher breakdown voltage. The method includes a thermal process for eliminating concentrated self-interstitial defects in the monocrystalline silicon wafer. The thermal process includes rapid thermal processing and/or prolonged thermal processing. That is, a monocrystalline silicon wafer free of self-interstitial defects can be obtained by performing the thermal process on the wafer, resulting in improved performance of semiconductor devices fabricated from the wafer.

### CROSS-REFERENCE TO RELATED APPLICATIONS

This application is a continuation application of International Patent Application No. PCT/CN2024/122783, filed with the China National Intellectual Property Administration on Sep. 30, 2024, entitled “Monocrystalline Silicon Wafer and Forming Method Therefore”, which claims the benefits of and priority to Chinese patent application No. 202311324353.2 filed Oct. 12, 2023, entitled “Monocrystalline Silicon Wafer and Forming Method Therefore”, the content of all of which is incorporated herein by reference in their entirety.

### TECHNICAL FIELD

The present invention relates to the field of semiconductor technology and, in particular, to a monocrystalline silicon wafer and a method of forming the wafer.

### BACKGROUND

Silicon wafers are the most important substrate material in the integrated circuit industry, and large silicon wafers have dominated the market. Most currently available large silicon wafers are obtained by the Czochralski (Cz) method. However, due to inevitable non-ideal conditions for crystal growth, existing Cz monocrystalline silicon wafers contain intrinsic defects.

According to the v/G criterion for crystal growth, intrinsic defects in Cz single crystal silicon are substantially self-interstitials and vacancies. Such self-interstitial defects, represented by dislocations, may deteriorate the performance of devices fabricated from the silicon, for example, due to increased leakage, a lower breakdown voltage or the like.

At present, most silicon wafer manufacturers have chosen to resort to reasonable control of Cz growth parameters, such as rate of pulling, magnetic field parameters, heater settings, and so forth. However, due to a vast diversity of such parameters, this control is extremely difficult. Therefore, there is a critical need for a different method capable of eliminating self-interstitial defects in a Cz monocrystalline silicon wafer.

### SUMMARY

The present invention seeks to solve the problem of eliminating self-interstitial defects in a monocrystalline silicon wafer by presenting a monocrystalline silicon wafer and a method of forming the wafer.

To this end, the present invention provides a monocrystalline silicon wafer including an upper surface and a first region located within a predefined distance from the upper surface. The first region is free of self-interstitial defects.

Optionally, the monocrystalline silicon wafer may further include a lower surface and a second region located within a predefined distance from the lower surface, wherein the upper surface and the lower surface are arranged opposite to each other, and the second region is free of self-interstitial defects.

Optionally, the predefined distance from the upper surface or the lower surface may be less than 20 μm.

Optionally, the predefined distance from the upper surface or the lower surface may range from 1 μm to 10 μm.

Optionally, the predefined distance from the upper surface or the lower surface may range from 1 μm to 5 μm.

Optionally, the monocrystalline silicon wafer may have a size, which is one of 6 inches, 8 inches, 12 inches and 18 inches.

The present invention also provides a method of forming a monocrystalline silicon wafer, which belongs to the same inventive concept and includes: providing a monocrystalline silicon ingot containing self-interstitial defects; obtaining the monocrystalline silicon wafer by performing a slicing process, which includes an upper surface and a first region located within a predefined distance from the upper surface; and eliminating those of the self-interstitial defects in the first region of the monocrystalline silicon wafer by performing a thermal process.

Optionally, the monocrystalline silicon wafer may further include a lower surface and a second region located within a predefined distance from the lower surface, wherein the upper surface and the lower surface are arranged opposite to each other, and those of the self-interstitial defects in the second region of the monocrystalline silicon wafer are also eliminated by the thermal process.

Optionally, the thermal process may include rapid thermal processing and/or prolonged thermal processing.

Optionally, the rapid thermal processing may be performed at a temperature of higher than 1100 °C for a duration ranging from 10 seconds to 240 seconds.

Optionally, the prolonged thermal processing may be performed at a temperature in the range of 1000 °C to 1250 °C for a duration ranging from 0.5 hours to 20 hours.

Optionally, the protective atmosphere for the rapid thermal processing may be selected from the group consisting of pure nitrogen, pure argon, and a mixed gas of argon and nitrogen, and wherein the protective atmosphere for the prolonged thermal processing is nitrogen.

Optionally, the monocrystalline ingot may be obtained by zone melting method or the Czochralski method.

Optionally, the monocrystalline ingot may be subjected to cropping and diameter grinding processes prior to the slicing process and to chamfering, grinding and polishing processes after the slicing process.

Optionally, after the thermal process is completed, the monocrystalline silicon wafer may be subjected to secondary polishing and final cleaning processes for removing nitride layers from the surfaces of the monocrystalline silicon wafer.

### BRIEF DESCRIPTION OF THE DRAWINGS

Those of ordinary skill in the art will understand that the following drawings are presented to enable a better understanding of the present invention and not intended to limit the scope thereof in any sense, in which:

FIG. 1 shows a schematic representation of a monocrystalline silicon wafer according to an embodiment of the present invention;

FIG. 2 shows a flowchart of a method of forming a monocrystalline silicon wafer according to an embodiment of the present invention;

FIG. 3 schematically illustrates a distribution of self-interstitial defects in a monocrystalline silicon wafer before it is subjected to a thermal process according to an embodiment of the present invention;

FIG. 4 schematically illustrates a distribution of self-interstitial defects in a monocrystalline silicon wafer that has been subjected to rapid thermal processing according to an embodiment of the present invention; and

FIG. 5 schematically illustrates a distribution of self-interstitial defects in a monocrystalline silicon wafer that has been subjected to prolonged thermal processing according to an embodiment of the present invention.

### List of Reference Numerals

10 monocrystalline silicon wafer; 10a upper surface; 10b lower surface; 10c first region; 10d second region; 11 self-interstitial defect.

### DETAILED DESCRIPTION

The inventors’ research has revealed that there has been proposed a method for reducing intrinsic dislocations in a heavily boron-doped Cz (Cz) silicon wafer, which includes placing the heavily boron-doped Cz silicon wafer in an atmosphere of 99.99% or more pure argon at 1000 to 1100 °C for 1 to 2 hours, followed by natural cooling, wherein the Cz silicon wafer is heavily doped with boron at a concentration of 7×10¹⁹ to 1.1×10²⁰ cm⁻³. This method has the advantages of a simple process, easy operation, ability to rapidly and effectively reduce, or even eliminate, intrinsic dislocations in a heavily boron-doped Cz silicon wafer and hence improve its quality, and particular applicability to Cz silicon wafers heavily doped with boron at a concentration in the range of from 7×10¹⁹ to 1.1×10²⁰ cm⁻³. Despite such good performance in removing intrinsic dislocations from a heavily boron-doped Cz silicon wafer, it requires doping with boron at a concentration of 7×10¹⁹ to 1.1×10²⁰ cm⁻³ and is therefore somewhat limited in application. Moreover, this method does not show comparably good performance for other types of silicon wafers, such as lightly boron-doped silicon wafers, float-zone (FZ) silicon wafers, etc. and imposes certain requirements on the thermal processing atmosphere. Therefore, there is a need for a more generally applicable method for removing self-interstitial defects from a silicon crystal.

In view of the above, the present invention provides a monocrystalline silicon wafer and a method of forming the wafer. The monocrystalline silicon wafer includes an upper surface and a first region located within a predefined distance from the upper surface. The monocrystalline silicon wafer also includes a lower surface and a second region located within the predefined distance from the lower surface. The upper and lower surfaces are arranged opposite to each other, and the first and second regions are free of self-interstitial defects. Semiconductor devices fabricated from such a monocrystalline silicon wafer free of self-interstitial defects will exhibit improved performance because of less leakage and a higher breakdown voltage. The method includes a thermal process for eliminating concentrated self-interstitial defects in the monocrystalline silicon wafer. The thermal process includes rapid thermal processing and/or prolonged thermal processing. That is, a monocrystalline silicon wafer free of self-interstitial defects can be obtained by performing the thermal process on the wafer, resulting in improved performance of semiconductor devices fabricated from the wafer.

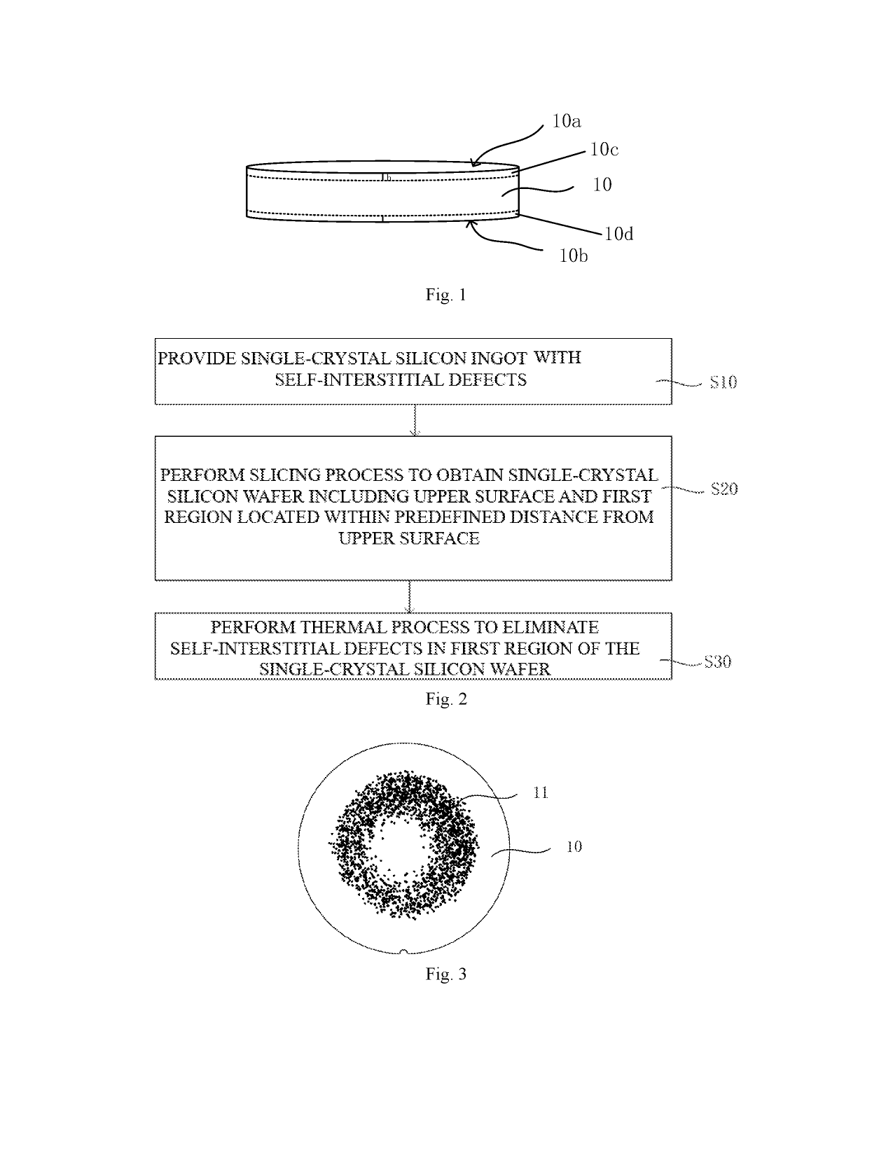

FIG. 1 shows a schematic representation of a monocrystalline silicon wafer according to an embodiment of the present invention. As shown in FIG. 1, the monocrystalline silicon wafer 10 includes an upper surface 10a, a lower surface 10b, a first region 10c located within a predefined distance from the upper surface and a second region 10d located within the predefined distance from the lower surface. The upper surface 10a and the lower surface 10b are arranged opposite to each other, and the first region 10c and the second region 10d are free of self-interstitial defects. The predefined distance h from the upper surface 10a or the lower surface 10b is less than 20 μm, for example. In a further embodiment disclosed herein, the predefined distance h from the upper surface 10a or the lower surface 10b may be 1 μm to 10 μm, for example. In a further embodiment disclosed herein, the predefined distance h from the upper surface 10a or the lower surface 10b may be 1 μm to 5 μm, for example. In other words, the first region 10c or second region 10d located within the predefined distance from a respective one of the surfaces may have a vertical height of up to 20 μm, and the first region 10c and the second region 10d are free of self-interstitial defects.

The monocrystalline silicon wafer 10 may contain carbon as an impurity at a concentration of, for example, lower than 0.01 ppma and interstitial oxygen at a concentration of higher than 8 ppma, preferably higher than 10 ppma, more preferably higher than 12 ppma. The concentration of interstitial oxygen atoms in the monocrystalline silicon wafer has an impact not only on the formation of micro-defects in the crystal but also on the mechanical properties of the monocrystalline silicon wafer. Therefore, the concentration (content) of oxygen and its concentration profile in the single silicon crystal are considered as important metrics for assessing intrinsic quality of the crystal. In the course of growing a silicon ingot or slicing a silicon wafer from the ingot, interstitial oxygen in the ingot may give rise to numerous defects during cooling of the ingot or subsequent fabrication of semiconductor devices therefrom. In particular, when treated at a temperature between 350 °C and 500 °C, oxygen induces so-called thermal donors, which are detrimental to the electrical properties of the material due to free electrons that they produce. At higher temperatures, oxygen precipitates and traps metal impurities in the silicon bulk, providing intrinsic gettering. In other words, for the monocrystalline silicon wafer of the present embodiment, the absence of self-interstitial defects, including those of types A (e.g., dislocations) and B (self-interstitial clusters), in the first region 10c and the second region 10d can be still ensured even when interstitial oxygen is present at a concentration of higher than 12 ppma therein.

The monocrystalline silicon wafer 10 may have a size, which is one of 6 inches, 8 inches, 12 inches and 18 inches. The monocrystalline silicon wafer 10 may be p-doped with, for example, boron, gallium, indium or the like, or n-doped with, for example, phosphorus, arsenic, antimony or the like. The monocrystalline silicon wafer 10 may be obtained by zone melting or the Cz method. The monocrystalline silicon wafer of the present embodiment, which is free of self-interstitial defects in the first region 10c and the second region 10d, is not limited to any particular type of monocrystalline silicon wafer. Rather, it may be of any of various sizes and doping types, and may contain interstitial oxygen at any of high concentrations. That is, the monocrystalline silicon wafer of the present embodiment, which is free of self-interstitial defects in the first region 10c and the second region 10d, provides wide applicability.

FIG. 2 shows a flowchart of a method of forming a monocrystalline silicon wafer according to an embodiment of the present invention. As shown, the method includes the steps of: S10) providing a monocrystalline silicon ingot containing self-interstitial defects; S20) obtaining the monocrystalline silicon wafer by performing a slicing process, which includes an upper surface and a first region located within a predefined distance from the upper surface; S30) eliminating those of the self-interstitial defects in the first region of the monocrystalline silicon wafer by performing a thermal process.

In step S10, the monocrystalline silicon ingot may be p-doped with, for example, boron, gallium, indium or the like, or n-doped with, for example, phosphorus, arsenic, antimony or the like. The monocrystalline silicon ingot may be obtained by zone melting or the Cz method. The monocrystalline silicon ingot as obtained contains self-interstitial defects, including those of types A (e.g., dislocations) and B (self-interstitial clusters). A-defects are large in size, structurally stable at high temperatures, and generally difficult to eliminate. B defects are small in size, unstable in structure at high temperatures, and easy to eliminate. This invention mainly focuses on eliminating A-defects.

Prior to step S20, the monocrystalline ingot may be subjected to cropping and diameter grinding process. The cropping process is performed to remove leading, trailing and any other unwanted portions of the monocrystalline ingot so that the remainder has a length suitable for processing on a slicer. Specimens may be taken from the monocrystalline silicon ingot for testing of its resistivity and oxygen content. The diameter grinding process is necessary because an outer diameter surface of the cropped monocrystalline ingot is not smooth enough, and since its diameter exceeds a specified diameter of the monocrystalline silicon wafer 10 after it is polished. After the outer diameter grinding, the ingot will have an accurate diameter.

In step S20, the monocrystalline silicon wafer 10 is obtained by slicing the ingot. The monocrystalline silicon wafer 10 includes an upper surface 10a, a lower surface 10b, a first region 10c located within a predefined distance from the upper surface and a second region 10d located within the predefined distance from the lower surface. The upper surface 10a and the lower surface 10b are arranged opposite to each other Specifically, the monocrystalline ingot is diced into wafers with well-defined dimensions.

After step S20 is completed, the monocrystalline silicon wafer is subjected to chamfering, grinding and polishing processes. The chamfering process is first performed to grind edges of the monocrystalline silicon wafer using a diamond grinding wheel to eliminate any pointed burrs, reduce edge chipping and relieve stress, preventing edge cracking of the monocrystalline silicon wafer and the formation of defects that may degrade its quality. The grinding process follows and involves grinding away saw marks and damaged surface layers caused by the slicer and grinding wheel, imparting effectively improved warpage, flatness and parallelism to the monocrystalline silicon wafer and allowing it to be processed in the subsequent polishing process. After this process is completed, both the upper surface 10a and the lower surface 10b are smooth enough to facilitate the subsequent polishing process. The polishing process involves increasing flatness of the upper surface 10a and the lower surface 10b of the monocrystalline silicon wafer to an extremely high level, i.e., reducing their roughness to an extremely low level. Desirably, the surfaces from this process are free of alternations or scratches.

In step S30, a thermal process is performed to eliminate self-interstitial defects in the first region 10c and the second region 10d of the monocrystalline silicon wafer. In particular, the monocrystalline silicon wafer may be placed into an annealing furnace, and the thermal process may be performed thereon in the furnace. The thermal process involves rapid thermal processing and/or prolonged thermal processing. That is, the thermal process may involve either rapid or prolonged thermal processing, or rapid thermal processing may be followed by prolonged thermal processing in this process. The rapid thermal processing may be carried out at a temperature of higher than 1100 °C for a period of 10 seconds to 240 seconds under the protection of a pure nitrogen or argon or mixed argon/nitrogen atmosphere. The prolonged thermal processing may be carried out at a temperature of 1000 °C to 1250 °C for a period of 0.5 hours to 20 hours under the protection of a nitrogen atmosphere.

After step S30, more precisely, the thermal process is completed, the monocrystalline silicon wafer 10 is subjected to secondary polishing and final cleaning processes for removing nitride layers from the surfaces of the monocrystalline silicon wafer 10. Amorphous nitride layers (not shown) may be formed on the upper surface 10a and the lower surface 10b of the monocrystalline silicon wafer in the thermal process and removed by performing the secondary polishing and final cleaning processes. The final cleaning process is performed to remove all contaminants from the surfaces of the monocrystalline silicon wafer.

The inventors have conducted a verification experiment on two monocrystalline silicon wafers sliced from a monocrystalline ingot obtained, for example, by the Cz method. The wafers have been polished into (mirror-surface wafers), and the monocrystalline ingot contains carbon at a concentration of, for example, less than 0.01 ppma and oxygen at a concentration of, for example, 10 ppma (as measured using Fourier transform infrared spectroscopy (FTIR)) and is, for example, p-doped, for example, with boron. The wafers are obtained in an annealing furnace under the protection of a pure nitrogen atmosphere. A thermal process is performed on the resulting monocrystalline silicon wafers to eliminate self-interstitial defects therein. Specifically, in this process, one of the wafers is subjected to rapid thermal processing, i.e., rapid thermal annealing, at a temperature of, for example, 1250 °C, for a period of, for example, 90 s, while the other wafer is subjected to prolonged thermal processing, i.e., prolonged thermal annealing, at a temperature of, for example, 1200 °C, for a period of, for example, 4 hours. In the thermal process, nitride layers are formed on the upper surface 10a and the lower surface 10b of the monocrystalline silicon wafers. These nitride layers are removed from the upper surface 10a and the lower surface 10b of the monocrystalline silicon wafers using secondary polishing and final cleaning processes.

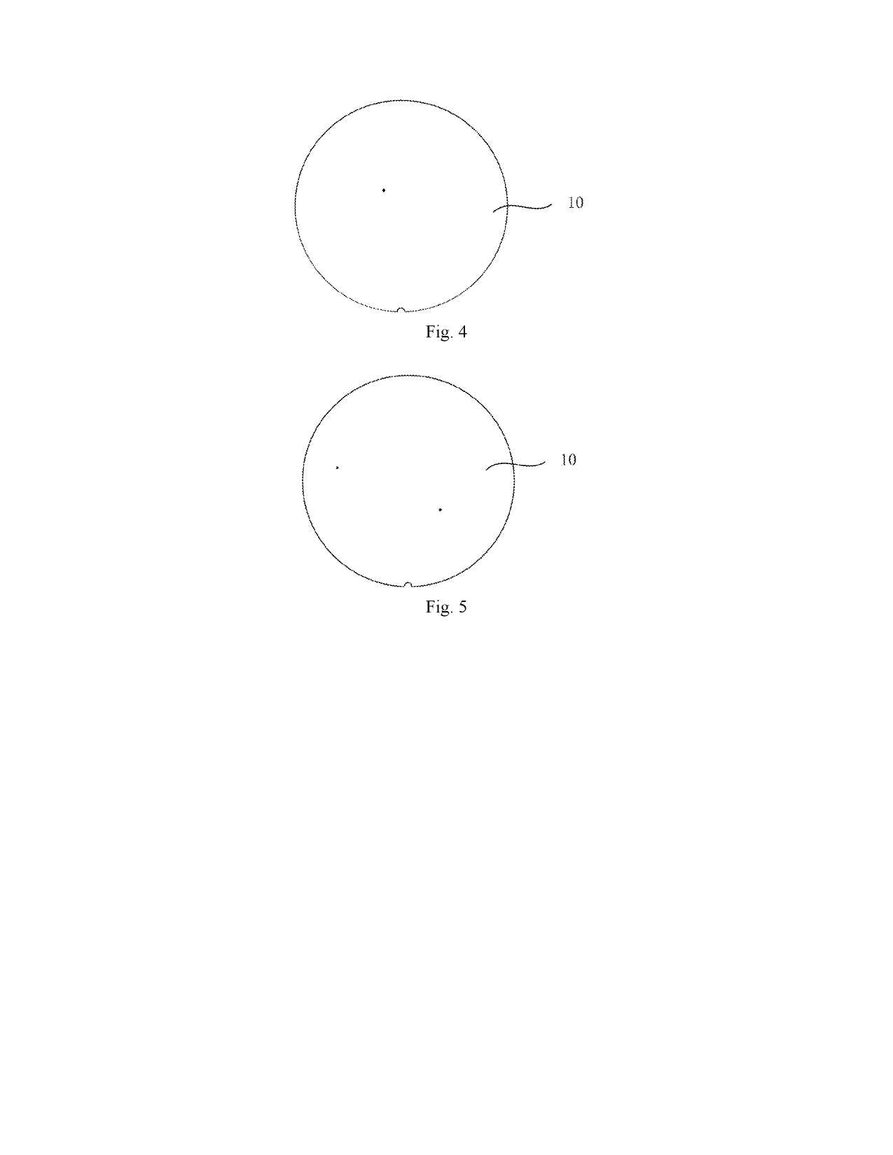

The monocrystalline silicon wafers are optically characterized for intrinsic self-interstitial defects therein before and after the thermal process. The optical characterization involves: scanning the surfaces of the monocrystalline silicon wafers using a laser scattering approach; computationally locating, and determining an equivalent size of, convexities or concavities in the monocrystalline silicon wafers; and deriving distributions of the self-interstitial defects. FIG. 3 schematically illustrates the distribution of self-interstitial defects in each monocrystalline silicon wafers prior to the thermal process. FIG. 4 schematically illustrates the distribution of self-interstitial defects in the monocrystalline silicon wafer that has been subjected to the rapid thermal processing. FIG. 5 schematically illustrates the distribution of self-interstitial defects in the monocrystalline silicon wafer that has been subjected to the prolonged thermal processing. As shown in FIG. 3, there are a great number of self-interstitial defects 11 on a surface of the monocrystalline silicon wafer. In FIGS. 4 and 5, there are almost no self-interstitial defects on a surface of each monocrystalline silicon wafer. Accordingly, a monocrystalline silicon wafer free of self-interstitial defects can be obtained by subjecting it to a thermal process.

In summary, embodiments disclosed herein provide a monocrystalline silicon wafer and method of forming the wafer. The monocrystalline silicon wafer includes an upper surface and a first region located within a predefined distance from the upper surface, and the first region is free of self-interstitial defects. Semiconductor devices fabricated from such a monocrystalline silicon wafer free of self-interstitial defects will exhibit improved performance because of less leakage and a higher breakdown voltage. The method includes a thermal process for eliminating concentrated self-interstitial defects in the monocrystalline silicon wafer. The thermal process includes rapid thermal processing and/or prolonged thermal processing. That is, a monocrystalline silicon wafer free of self-interstitial defects can be obtained by performing the thermal process on the wafer, resulting in improved performance of semiconductor devices fabricated from the wafer.

1. A monocrystalline silicon wafer, comprising an upper surface and a first region located within a predefined distance from the upper surface, the first region is free of self-interstitial defects.

2. The monocrystalline silicon wafer according to claim 1, further comprising a lower surface and a second region located within a predefined distance from the lower surface, wherein the upper surface and the lower surface are arranged opposite to each other, and wherein the second region is free of self-interstitial defects.

3. The monocrystalline silicon wafer according to claim 1, wherein the predefined distance from the upper surface or the lower surface is less than 20 μm.

4. The monocrystalline silicon wafer according to claim 3, wherein the predefined distance from the upper surface or the lower surface ranges from 1 μm to 10 μm.

5. The monocrystalline silicon wafer according to claim 4, wherein the predefined distance from the upper surface or the lower surface ranges from 1 μm to 5 μm.

6. The monocrystalline silicon wafer according to claim 1, wherein a size of the monocrystalline silicon wafer is one of 6 inches, 8 inches, 12 inches and 18 inches.

7. A method of forming a monocrystalline silicon wafer, comprising:
providing a monocrystalline silicon ingot with self-interstitial defects;
obtaining the monocrystalline silicon wafer by performing a slicing process, which comprises an upper surface and a first region located within a predefined distance from the upper surface; and
eliminating those of the self-interstitial defects in the first region of the monocrystalline silicon wafer by performing a thermal process.

8. The method of forming the monocrystalline silicon wafer according to claim 7, wherein the monocrystalline silicon wafer further comprises a lower surface and a second region located within a predefined distance from the lower surface, wherein the upper surface and the lower surface are arranged opposite to each other, and those of the self-interstitial defects in the second region of the monocrystalline silicon wafer are also eliminated by the thermal process.

9. The method of forming the monocrystalline silicon wafer according to claim 7, wherein the thermal process comprises a rapid thermal processing and/or a prolonged thermal processing.

10. The method of forming the monocrystalline silicon wafer according to claim 9, wherein the rapid thermal processing is performed at a temperature of higher than 1100 °C for a duration ranging from 10 seconds to 240 seconds.

11. The method of forming the monocrystalline silicon wafer according to claim 9, wherein the prolonged thermal processing is performed at a temperature in the range of 1000 °C to 1250 °C for duration ranging from 0.5 hours to 20 hours.

12. The method of forming the monocrystalline silicon wafer according to claim 9, wherein the protective atmosphere for the rapid thermal processing is selected from the group consisting of pure nitrogen, pure argon, and a mixed gas of argon and nitrogen, and wherein the protective atmosphere for the prolonged thermal processing is nitrogen.

13. The method of forming the monocrystalline silicon wafer according to claim 7, wherein the monocrystalline ingot is obtained by a zone melting method or a Czochralski method.

14. The method of forming the monocrystalline silicon wafer according to claim 7, wherein the monocrystalline ingot is subjected to cropping and diameter grinding processes prior to the slicing process, and wherein the monocrystalline ingot is subjected to chamfering, grinding and polishing processes after the slicing process.

15. The method of forming the monocrystalline silicon wafer according to claim 7, wherein after the thermal process is completed, the monocrystalline silicon wafer is subjected to secondary polishing and final cleaning processes for removing
nitride layers from the surfaces of the monocrystalline silicon wafer.
